(19) United States
(12) Patent Application Publication
(10) Pub. No.: US 2025/0372475 A1
(43) Pub. Date: Dec. 4, 2025

(54) Heat-Dissipating Lid Module

(71) Applicant: Taiwan Semiconductor Manufacturing Company, Ltd., Hsin-Chu (TW)

(72) Inventors: Chien-Chang WANG, Hsinchu City (TW); Kuan-Min WANG, Hsinchu City (TW); Bang Li WU, Hsinchu City (TW); Kuo-Chin CHANG, Hsinchu (TW); Kathy Wei YAN, Hsinchu (TW); Jun HE, Zhubei City (TW)

(21) Appl. No.: 18/679,798

(22) Filed: May 31, 2024

(51) Int. Cl. H01L 23/367; H01L 23/00; H01L 23/38; H01L 23/427; H01L 25/065

(52) U.S. Cl. CPC H01L 23/3675; H01L 23/38; H01L 23/427; H01L 25/0655; H01L 24/16; H01L 24/32; H01L 24/73; H01L 2224/16225; H01L 2224/32225; H01L 2224/73204; H01L 2924/1436

(57) ABSTRACT

An exemplary package structure includes a package substrate; an integrated circuit (IC) package comprises one or more dies and having a first side and a second side opposite the first side, wherein the first side of the IC package is attached to the package substrate; a heat-dissipating lid module attached to the second side of the IC package, wherein the heat-dissipating lid module comprises an upper portion, a lower portion, and a middle portion disposed between and thermally coupled to the upper portion and the lower portion, wherein the middle portion includes a heat sink separating the heat-dissipating lid module into a liquid cooling system and a vapor chamber.

### BACKGROUND

Advanced integrated circuit (IC) packaging technologies have been explored to further reduce density and/or improve performance of ICs. For example, IC packaging has evolved, such that multiple ICs may be vertically stacked in three-dimensional (“3D”) packages or 2.5D packages (e.g., packages that implement an interposer). 3D IC packages and/or 2.5D IC packages may reduce footprints (e.g., by allowing for a greater number of components to be placed in a given chip area), reduce power consumption (e.g., by reducing lengths of signal interconnects), improve yield, reduce fabrication costs, or combinations thereof. However, as more components and/or more chips are packed into smaller areas, thermal dissipation and/or thermal management has become a key challenge facing IC packaging technologies.

### BRIEF DESCRIPTION OF THE DRAWINGS

The present disclosure is best understood from the following detailed description when read with the accompanying figures. It is emphasized that, in accordance with standard practice in the industry, various features are not drawn to scale and are used for illustration purposes only. For example, dimensions of the various features may be arbitrarily increased or decreased for clarity of discussion. It is also emphasized that the accompanying figures illustrate example embodiments and are therefore not to be considered limiting in scope.

FIG. 1 is a flow chart of a method, in portion or entirety, for forming a package structure including a heat-dissipating lid module over an IC package, such as those described herein, according to various aspects of the present disclosure.

FIGS. 2A, 2B, 2C, and 2D are cross-sectional views of the IC package, in portion or entirety, at various stages of the method of FIG. 1, according to various aspects of the present disclosure.

FIG. 3A is a cross-sectional view of the heat-dissipating lid module, in portion or entirety, according to various aspects of the present disclosure.

FIG. 3B depicts a simplified exploded view of the heat-dissipating lid module, in portion or entirety, according to various aspects of the present disclosure.

FIG. 3C depicts an enlarged view of a portion of the heat-dissipating lid module, according to various aspects of the present disclosure.

FIG. 3D depicts an enlarged view of a portion of an alternative heat-dissipating lid module, according to various aspects of the present disclosure.

FIG. 4 depicts a fragmentary cross-sectional view of the package structure, according to various aspects of the present disclosure.

FIG. 5 depicts a cross-sectional view of a first alternative package structure, in portion or entirety, according to various aspects of the present disclosure.

FIG. 6 depicts schematic plan views illustrating an IC package and a portion of a heat-dissipating lid module of a second alternative package structure, according to some embodiments of the present disclosure.

FIG. 7 depicts a fragmentary cross-sectional view of the second alternative package structure shown in FIG. 6, according to various aspects of the present disclosure.

FIG. 8 depicts an enlarged view of a portion of the second alternative package structure, according to various aspects of the present disclosure.

FIG. 9 depicts schematic plan views illustrating an IC package and a portion of a heat-dissipating lid module of a third alternative package structure, according to some embodiments of the present disclosure.

FIG. 10 depicts a fragmentary cross-sectional view of a fourth alternative package structure, according to various aspects of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Further, when a number or a range of numbers is described with “about,” “approximate,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” can encompass a dimension range from 4.25 nm to 5.75 nm where manufacturing tolerances associated with depositing the material layer are known to be +/−15% by one of ordinary skill in the art. Still further, the present disclosure may repeat reference numerals and/or letters in the various examples. This repetition is for the purpose of simplicity and clarity and does not in itself dictate a relationship between the various embodiments and/or configurations discussed.

To meet the continued demands of delivering advanced integrated circuits (ICs), IC dimensions (e.g., minimum IC feature size) have continued to be scaled down. Though downscaling of IC dimensions has boosted device performance and increased device density, the increased device density has also increased power density, which in turn has caused IC thermal management to become a key challenge in the development of advanced ICs and advanced IC packages. For example, an IC package may house an IC die (also referred to as a chip) between a lid and a package substrate, where the lid is configured and designed to dissipate heat from the IC die. There is always a need to improve the heat dissipation efficiency.

The present disclosure addresses such challenges by providing a heat-dissipating lid module having a liquid cooling system thermally coupled to a vapor chamber, where the liquid cooling system includes a heat sink, and a base plate of the heat sink also serves as a top wall of the vapor chamber. In some embodiments, the heat-dissipating lid module also includes thermoelectric coolers placed on the bottom surface of the base plate of the heat sink to improve phase change process (from vapor phase to liquid phase) in the vapor chamber. The thermoelectric coolers may include multi-stage thermoelectric coolers to further increase the phase change process (from vapor phase to liquid phase) at various locations in the vapor chamber to eliminate hot spots. Since there is no additional material disposed between the liquid cooling system and the vapor chamber to attach the two heat dissipating systems, thermal resistance therebetween is reduced, and thus better thermal conductivity is achieved. Different embodiments may have different advantages, and no particular advantage is required of any embodiment.

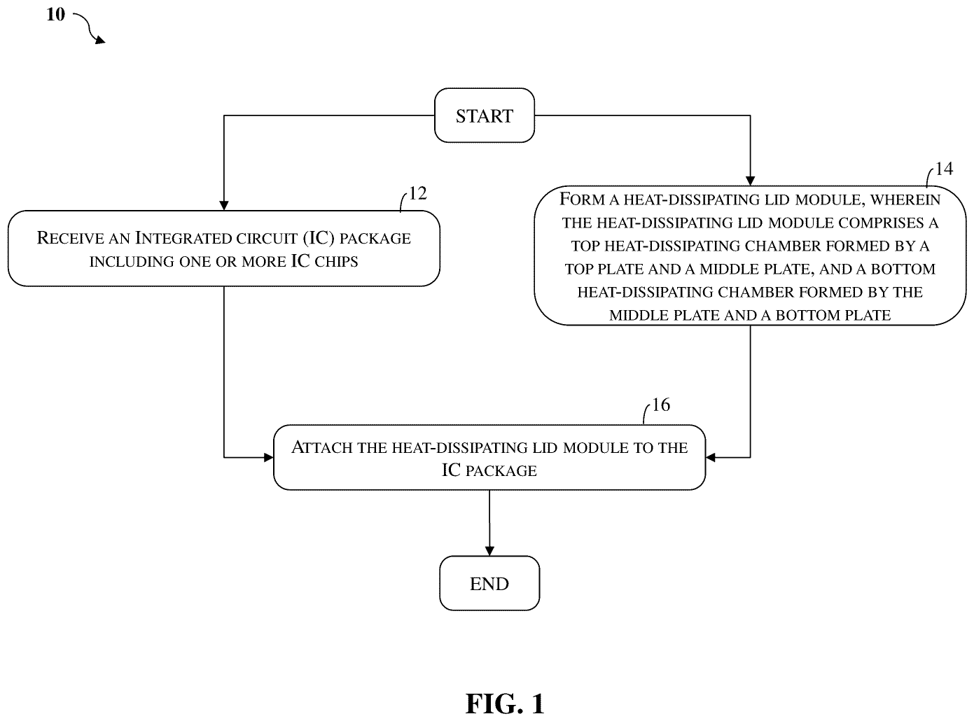

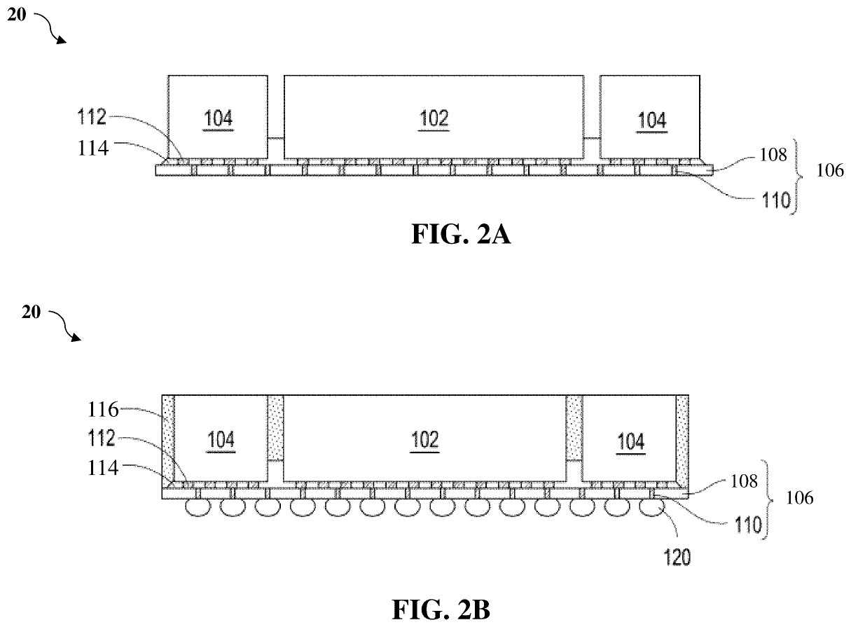

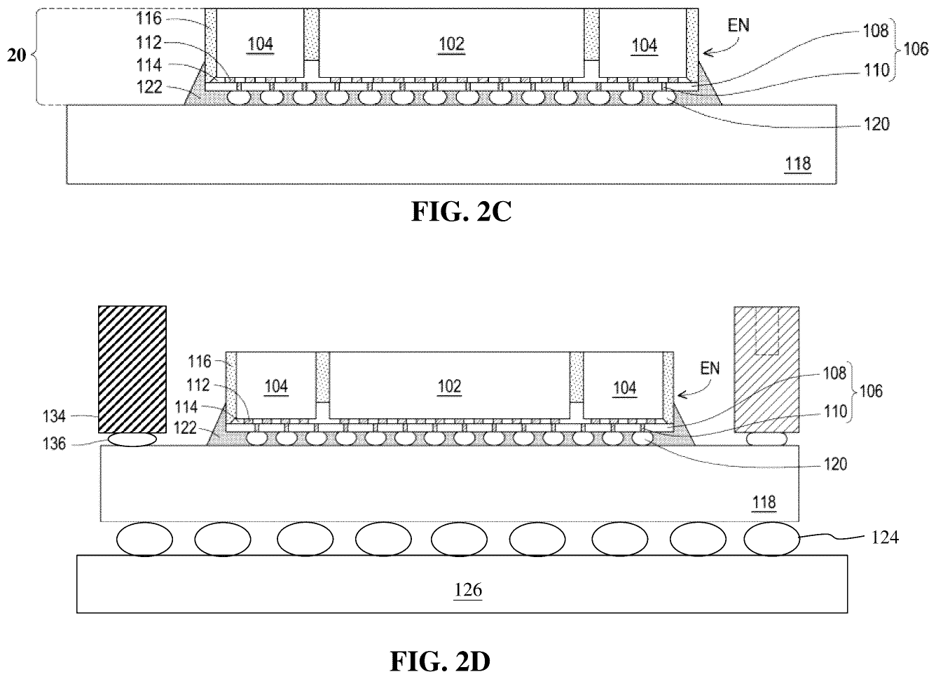

FIG. 1 is a flow chart of a method 10, in portion or entirety, for forming a package structure 40 including a heat-dissipating lid module 30 over an integrated circuit (IC) package 20, such as those described herein, according to various aspects of the present disclosure. Referring to FIG. 1 and FIGS. 2A-2D, method 10 includes a block 12 where an integrated circuit (IC) package 20 is received. FIGS. 2A, 2B, 2C, and 2D are schematic cross-sectional views illustrating intermediate structures at various stages during a manufacturing process for forming the IC package 20, according to various aspects of the present disclosure.

Referring to FIG. 2A, the IC package 20 includes a die 102 and dies 104 aside the die 102. The die 102 and the dies 104 may be arranged side by side, and are laterally separated with one another. In some embodiments, each of the die 102 and the dies 104 may be a central processing unit (CPU), a graphics processing unit (GPU), a memory, such as a static random-access memory (SRAM). In some embodiments, such as in the depicted embodiment, die 102 is a system-on-chip (SoC) device die, which generally refers to a single chip and/or monolithic die having multiple functions. In some embodiments, the SoC is a single chip having an entire system, such as a computer system, fabricated thereon. Each of the dies 104 may include a memory die or a stack of memory dies (e.g., high bandwidth memory (HBM) dies).

The die 102 and dies 104 are attached to an interposer 106. The interposer 106 may include a semiconductor substrate 108 (e.g., a silicon substrate) and through substrate vias (TSV) 110 penetrating through the semiconductor substrate 108. The TSVs 110 are electrically connected to the die 102 and the dies 104, and establish conduction paths extending between opposite sides of the semiconductor substrate 108. Although not shown, the interposer 106 may further include metallization layers at one or both sides of the semiconductor substrate 108, and the TSVs 110 may be connected to one or both sides of the interposer 106 through interconnection elements (e.g., a combination of conductive lines and conductive vias) in the metallization layers. In some embodiments, the interposer 106 may include a stack of polymer layers and interconnection elements spreading in the stack of polymer layers. In other embodiments, the interposer 106 may include a molding compound substrate with vias penetrating through, and may further include metallization layers at one or both sides of the molding compound substrate. Interconnection elements (e.g., a combination of conductive lines and conductive vias) in the metallization layers may be electronically connected to the vias extending through the molding compound substrate. In some embodiments, the die 102 and the dies 104 are attached to the interposer 106 via the electrical connectors 112. As an example, the electrical connectors 112 may be micro-bumps. The electrical connectors 112 are laterally surrounded by an underfill 114 spreading in a space between the interposer 106 and the attached die 102 and dies 104. In some embodiments, the underfill 114 includes an organic material, such as an epoxy-based material. In some embodiments, the underfill 114 includes a material that improves mechanical reliability of IC package 20 by distributing stresses across a die-side surface of IC package 20 rather than allowing such stresses to become concentrated. In some embodiments, underfill 114 includes a material that protects connectors 112 from moisture and/or contaminants.

Referring to FIG. 2B, the die 102 and the dies 104 attached on the interposer 106 are laterally encapsulated by an encapsulant 116. The encapsulant 116 may be provided on the underfill 114, and laterally surround the die 102 and the dies 104. Moreover, the electrical connectors 120 may be formed at a side of the interposer 106 facing away from the die 102 and the dies 104. The encapsulant 116 may circumferentially surround the dies 102 and 104. The encapsulant 116 may include an organic material, such as an epoxy-based material.

Referring to FIG. 2C, the IC package 20 is then attached to a package substrate 118 via the electrical connectors 120. In some embodiments, although not shown, the package substrate 118 includes a dielectric core layer and build-up layers at one or both sides of the dielectric core layer, and conductive wirings may spread in the build-up layers. In alternative embodiments, the package substrate 118 is a core-less substrate, and includes a stack of build-up layers and conductive wirings spreading in the stack of build-up layers. Signals from the die 102 and the dies 104 can be routed to another side of the package substrate 118 through the conductive wirings in the package substrate 118. After the attachment, underfill 122 may be further provided on the package substrate 118, to laterally surround the electrical connectors 120. In some embodiments, the underfill 122 may further extend to sidewalls of the interposer 106 and the encapsulated structure EN including the die 102 and the dies 104 laterally encapsulated by the encapsulant 116. Although not shown, other electronic components (e.g., passive devices) may optionally be attached onto the package substrate 118.

Referring to FIG. 2D, electrical connectors 124 are formed at a side of the package substrate 118 facing away from the interposer 106 and the encapsulated structure EN. As an example, the electrical connectors 124 may be ball grid array (BGA) balls. In some embodiments, an optional ring structure 134 may be attached onto the package substrate 118 via the adhesive 136. In addition, in some embodiments, the current structure is subjected to a thermal treatment for curing the adhesive 136. The electrical connectors 124 may be formed before or after formation of the ring structure 134 and the adhesive 136. In an embodiment, after forming the electrical connectors 124, the package substrate 118 may be attached to a printed circuit board (PCB) 126 through the electrical connectors 124. FIGS. 2A-2D are provided to illustrate an exemplary method of forming the IC package 20. It is noted that other fabrication processes of forming the IC package 20 are also possible. In some alternative embodiments, the IC package 20 may be a lidded IC package. Up to here, an IC package 20 has been formed on the package substrate 118. Subsequently, components will be formed on the IC package 20 and the package substrate 118 for facilitating heat dissipation of the IC package 20.

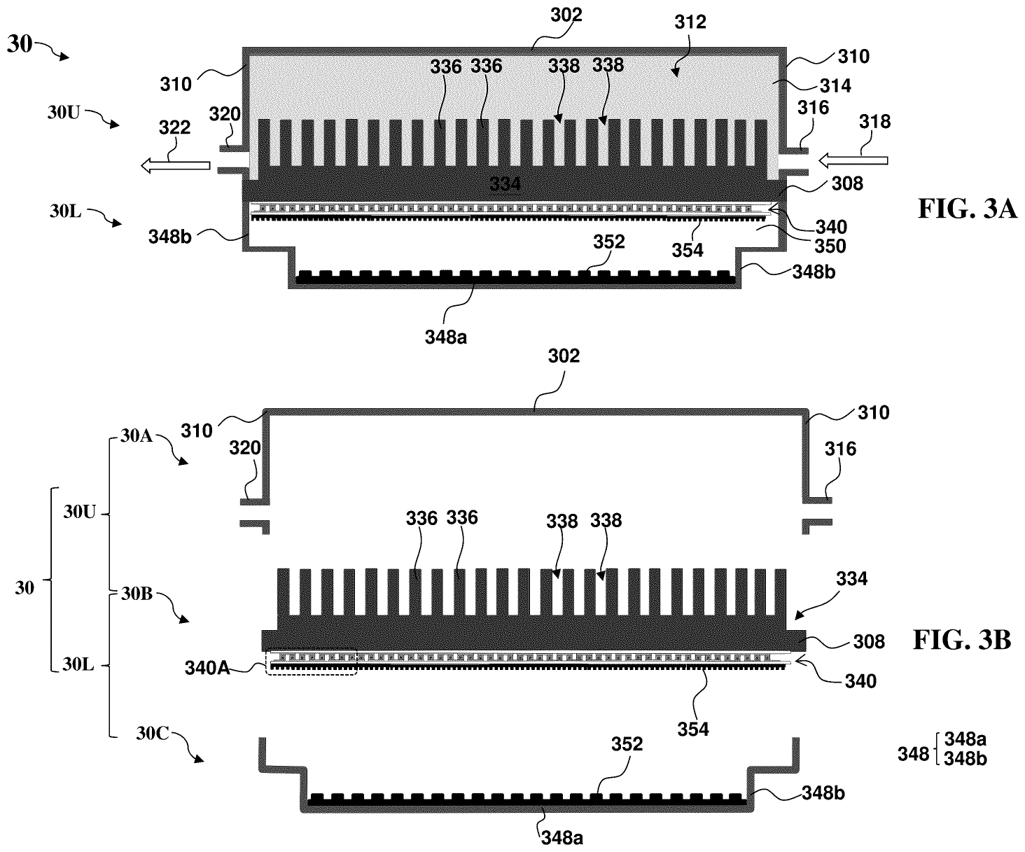

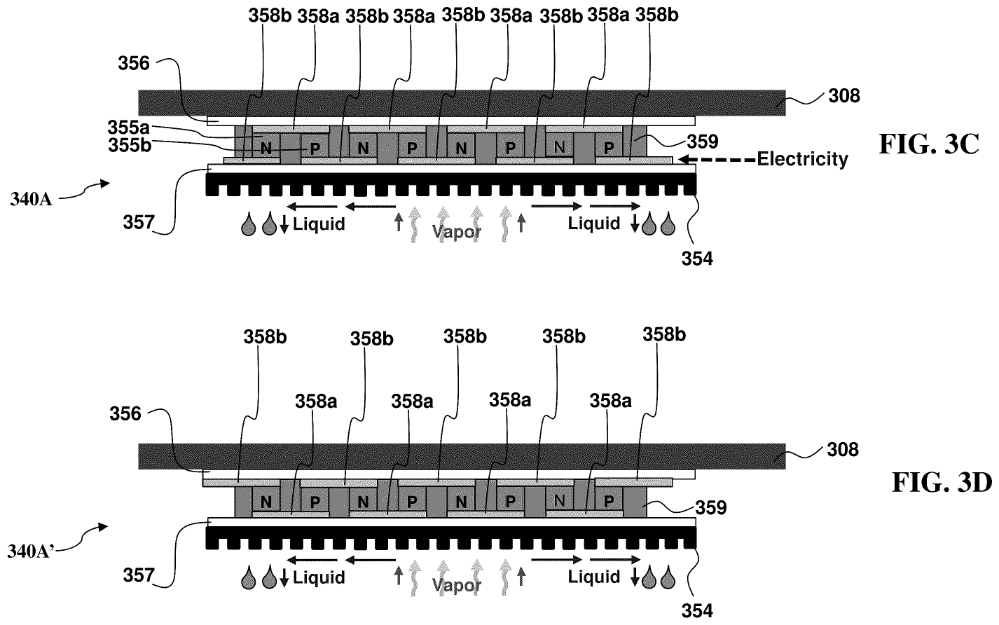

Referring back to FIG. 1, method 10 includes a block 14 where a heat-dissipating lid module 30 is provided. FIG. 3A is a cross-sectional view of the heat-dissipating lid module 30, in portion or entirety, according to various aspects of the present disclosure. FIG. 3B depicts a simplified exploded view of the heat-dissipating lid module 30, in portion or entirety, according to various aspects of the present disclosure.

As shown in FIG. 3A, the heat-dissipating lid module 30 includes a top portion 30A, a middle portion 30B, and a bottom portion 30C. In this illustrated embodiment, the top portion 30A and the middle portion 30B may form a liquid cooling system and thus may be collectively referred to a liquid cooling system 30U; the middle portion 30B and the bottom portion 30C may form a vapor chamber and thus may be collectively referred to a vapor chamber 30L.

More specifically, the top portion 30A includes a top wall 302 that is connected to a base plate 308 of the middle portion 30B through side walls 310. In combination, the top wall 302, side walls 310, and the base plate 308 of the middle portion 30B define a cavity 312 through which a flow of a cooling liquid 314 may be circulated. In this illustrated embodiment, the cavity 312 is substantially filled by the cooling liquid 314. As shown in this example, the side walls 310 include a cooling liquid inlet 316 through which a supply 318 of the cooling liquid 314 may enter. The side walls 310 also include a cooling liquid outlet 320 through which a return 322 of the cooling liquid 314 may exit. The cavity 312 defines or includes a cooling liquid flow path between the inlet 316 and the outlet 320. To improve heat dissipation efficiency, in an embodiment, the cooling liquid inlet 316 and the cooling liquid outlet 320 are placed closer to the middle portion 30B (e.g., the fins 336) than to the top wall 302. For example, a distance between the cooling liquid inlet 316 and the base plate 308 is less than a distance between the cooling liquid inlet 316 and the top wall 302. In an embodiment, the cooling liquid inlet 316 and the cooling liquid outlet 320 are placed laterally adjacent to the fins 336, and a distance between the fins 336 and the top wall 302 is less than a distance between the cooling liquid inlet 316 and the top wall 302.

The middle portion 30B includes the base plate 308 and fins 336 (ridges, or other extended surfaces that increase a heat transfer area) protruding from a top surface of the base plate 308. In an illustrated embodiment, the base plate 308 and the fins 336 are portions of an integral (one-piece, unibody) heat sink 334. When assembled with the top portion 30A, the fins 336 are positioned in the cavity 312. The fins 336 define channels (or trenches) 338, for example, through which the cooling liquid 314 may be circulated to increase an amount of heat transferred from the IC package 20 to the cooling liquid (e.g., relative to an amount transferred in an implementation of the package structure 40 that does not include the fins 336). In an embodiment, the fins 336 and channels 338 collectively span a width that is less than a width of the base plate 308 such that the base plate 308 may be assembled with the side walls 310 of the top portion 30A and side walls 348b of the bottom portion 30C. The channels 338 may or may not expose the top surface of the base plate 308. Alternative implementations of the liquid cooling system 30U of the package structure 40 may include multiple inlets 316, multiple outlets 320, or may not include the fins 336. The middle portion 30B also includes a cooler feature 340 formed under a bottom surface of the base plate 308 to improve the phase change process (e.g., vapor phase to liquid phase) happened inside the vapor chamber 30L and thus further improve thermal management. Details of the cooler feature 340 will be described with reference to FIGS. 3C and 3D.

The bottom portion 30C includes a bottom cover 348 having a bottom wall 348a and side walls 348b. In combination, the bottom cover 348 and the base plate 308 of the middle portion 30B define a hermetically sealed chamber 350 that is able to contain a heat transfer fluid (not shown). The heat transfer fluid is a two-phase vaporizable fluid (e.g., a fluid that may change between a gas phase (e.g., a vapor phase) and a liquid phase). The two-phase vaporizable fluid may be water, ethanol, methanol, refrigerant (e.g., freon), other two-phase vaporizable fluid, or combinations thereof. The vapor chamber 30L may also include condensing enhancements, such as wicking structures (e.g., wicking structure 352 and wicking structure 354) within the chamber 350 (e.g., on a bottom inner surface and/or a top inner surface of the vapor chamber 30L) to allow for better heat transfer from the fluid towards the base plate 308. Each of the wicking structure 352 and wicking structure 354 may be a thermally conductive, porous structure that may convey a working fluid by capillary action. Each of the wicking structure 352 and wicking structure 354 may be formed of a thermally conductive material, which may be copper, aluminum, other thermally conductive material, alloys thereof, or combinations thereof. Each of the wicking structure 352 and wicking structure 354 may be a grooved wick, a sintered wick, a mesh wick, other wick type, or combinations thereof. In the depicted embodiment, each of the wicking structure 352 and wicking structure 354 is a patterned copper structure, such as a copper grooved wick. In some embodiments, the wicking structure 352 is formed by depositing a copper-containing layer (e.g., by physical vapor deposition (PVD) or chemical vapor deposition (CVD)) and patterning the copper-containing layer (e.g., by forming a patterned mask layer over the copper-containing layer, etching the copper-containing layer using the patterned mask layer as an etch mask, and removing the patterned mask layer after the etching). The present disclosure contemplates various structures and processes for forming the wicking structure 352 and the wicking structure 354.

In this example, the vapor chamber 30L includes one single chamber 350 confined by the bottom cover 348 and the base plate 308 that enclose the fluid. In some other embodiments, the vapor chamber 30L may include multiple chambers laterally isolated from each other. As illustrated by FIG. 3A, the base plate 308 of the heat sink 334 separates the top portion 30A and the bottom portion 30C to form two discrete sealed space (i.e., the chamber (or “cavity”) 312 and the chamber (or “cavity”) 350).

The top wall 302, the bottom wall 348a, and at least parts of the side walls 310 and 348b of the heat-dissipating module 30 are thermally conductive and may be made of a material having a low coefficient of thermal expansion (CTE), such as copper, copper alloy, aluminum alloy. Other suitable materials may also be used so long as the material possesses at least a low coefficient of thermal expansion and high thermal conductivity. The heat sink 334 may be made of a material having a low coefficient of thermal expansion (CTE), such as copper, copper alloy, aluminum alloy. The housing of the top portion 30A and the housing of the bottom portion 30C may be made of a same material or different materials. The heat sink 334 be made of a material same as or different from that of the top portion 30A or the bottom portion 30C.

In an embodiment, after receiving the pieces (e.g., the top portion 30A, the middle portion 30B, and the bottom portion 30C), the side walls 310, the base plate 308, and the side walls 348b are connected together by, for example, a soldering process that is used to connect two discrete metallic components together. Other processes may also be used to assembly pieces of the heat-dissipating module 30. Thus, the discrete top portion 30A, the middle portion 30B, and the bottom portion 30C are soldered together to form module 30 having the sealed chamber 350 therebetween. The chamber 350 is in a vacuumed condition. The working liquid is received in the chamber 350. As described above, the vapor chamber 30L is connected to the liquid cooling system 30U through a part (i.e., heat sink 334) of the liquid cooling system 30U. As such, the heat-dissipating lid module 30 does not need thermal interface material (e.g., a phase change material or otherwise thermally conductive material) to mount the vapor chamber 30L to the liquid cooling system 30U. Thus, a conductive heat transfer efficiency between the vapor chamber 30L and the liquid cooling system 30U is improved. In various embodiments, the lid module 30 may be implemented in various packaging technologies, such as a chip-on-wafer-on-substrate (CoWoS) packaging technology, system-on-integrated-chips (SoIC) multi-chip packaging technology, an integrated-fan-out (InFO) package, according to various aspects of the present disclosure. Although specific dimensions vary depending upon different applications, in an embodiment, when the lid module 30 is applied to a CoWoS package having a size that is about 3.3 times of a reticle size, a size of the corresponding lid module 30 may be no less than 77.6 mm by 71.6 mm to provide satisfactory heat dissipation.

FIG. 3C depicts an enlarged view of a portion 340A of the cooler feature 340 the middle portion 30B of the heat-dissipating lid module 30, according to various aspects of the present disclosure. The cooler feature 340 includes a number of first regions 355a and a number of second regions 355b disposed between a first thermal conducting plate 356 and a second thermal conducting plate 357. In some embodiments, first regions 355a are n-type semiconductor pillars (may be hereinafter referred to as “semiconductor pillars 355a”) and second regions 355b are p-type semiconductor pillars (may be hereinafter referred to as “semiconductor pillars 355b”). Additional materials and design shapes can be used to construct the number of first regions 355a and the number of second regions 355b. In some embodiments, the first thermal conducting plate 356 and second thermal conducting plate 357 are made of ceramic, which is an effective heat conductor and an electrical insulator. Additional materials can be used to construct the first thermal conducting plate 356 and second thermal conducting plate 357. The semiconductor pillars 355a and 355b are electrically connected in series using electrical conductors (or traces) 358a. In some embodiments, electrical conductors 358a include copper or another electrically conductive material. A power source (not shown) provides electrical power to electrical conductors (or traces) 358b. When voltage is applied across the plurality of semiconductor pillars 355a, 355b, a temperature gradient is formed such that the first thermal conducting plate 356 is heated and the second thermal conducting plate 357 is cooled. The first thermal conducting plate 356 is attached to the base plate 308 of the heat sink 334 by various means. The wicking structure 354 is attached to the second thermal conducting plate 357 by various means. In an embodiment, an epoxy encapsulation layer 359 is formed to surround the semiconductor pillars 355a and 355b and the electrical conductors 358a and 358b to provide a moisture barrier for the cooler feature 340.

FIG. 3D depicts an enlarged view of a portion 340A′ of an alternative cooler feature, according to various aspects of the present disclosure. The alternative cooler feature is similar to the cooler feature 340, one of the differences include the different arrangements of electrical conductors 358a and 358b. For example, each electrical conductor 358a of the portion 340A (shown in FIG. 3C) connects a top surface of the first region 355a (e.g., n-type semiconductor pillar) to a top surface of the second region 355b (e.g., p-type semiconductor pillar), however, each electrical conductor 358a of the portion 340A′ (shown in FIG. 3D) connects a bottom surface of the first region 355a (e.g., n-type semiconductor pillar) to a bottom surface of the second region 355b (e.g., p-type semiconductor pillar). In addition, the electrical conductor 358b of the portion 340A connects a bottom surface of the second region 355b (e.g., p-type semiconductor pillar) to a bottom surface of the first region 355a (e.g., n-type semiconductor pillar), however, the electrical conductor 358b of the portion 340A′ connects a top surface of the second region 355b (e.g., p-type semiconductor pillar) to a top surface of the first region 355a (e.g., n-type semiconductor pillar).

In the present embodiments, the cooler feature 340 is a single-stage thermoelectric cooler (TEC). The cooler feature 340 may be a continuous thermoelectric cooler extending along a bottom surface of the base plate 308 of the heat sink 334. In another embodiment, the cooler feature 340 may include multiple discrete thermoelectric coolers electrically and physically isolated from each other such that those thermoelectric coolers can be individually controlled. For example, each of the discrete thermoelectric coolers may be coupled to a corresponding power source with respective electrical powers. By adjusting the electrical powers and thus adjusting the applied DC current, heat transfer efficiency of those discrete thermoelectric coolers may be individually adjusted. Accordingly, the wicking structure 354 may include multiple discrete wicks attached to the discrete thermoelectric coolers, respectively.

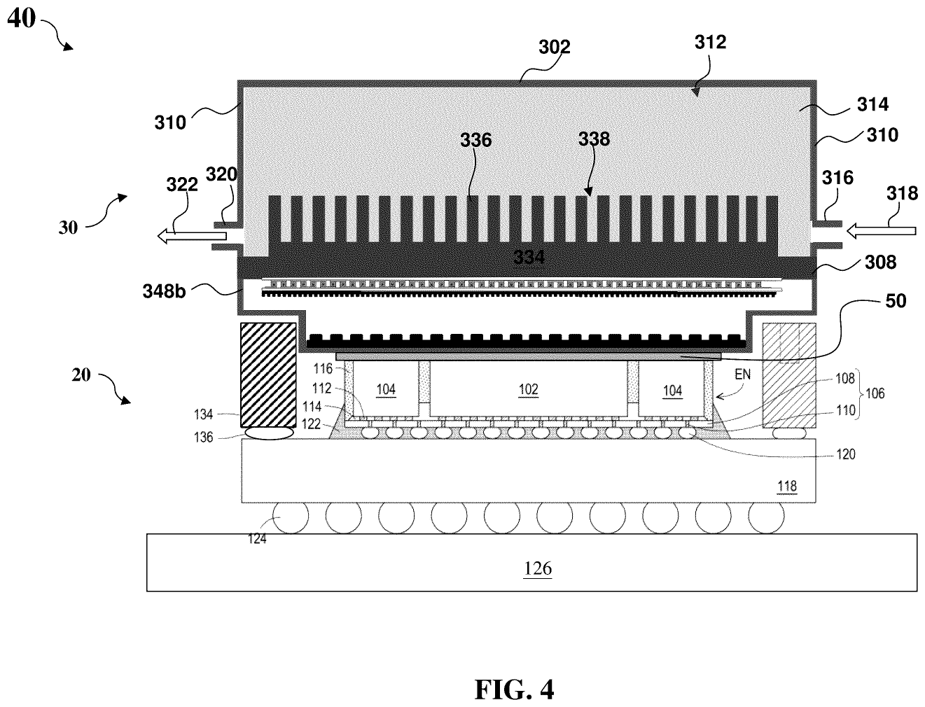

Referring back to FIG. 1, method 10 includes a block 16 where the heat-dissipating lid module 30 is attached to the integrated circuit (IC) package 20 to form the package structure 40. FIG. 4 depicts a fragmentary cross-sectional view of the package structure 40, according to various aspects of the present disclosure. In this illustrated embodiment, the heat-dissipating lid module 30 is attached to the IC package 20 by a thermal interface material (TIM) 50, such as a thermal grease and/or a thermal gel, to compensate for a coefficient of thermal expansion mismatch between the heat-dissipating lid module 30 and the IC package 20. Other possible ways to attach the heat-dissipating lid module 30 with the IC package 20 is also possible. In this illustrated embodiment, the lid module 30 does not contact the ring structure 134. In other alternative embodiments, the lid module 30 may be further attached to the IC package 20 (e.g., the ring structure 134 or other features of the IC package 20) by any suitable fixtures.

During an example operation of the package structure 40, the die 102 and the dies 104 of the IC package 20 generate heat that may need to be dissipated or removed from the package structure 40 (e.g., for proper operation of the package structure 40). Heat generated by the die 102 and the dies 104 of the IC package 20 is transferred through the thermal interface material 50 and to the bottom wall 348a of the vapor chamber 30L. The transferred heat is then transferred from the bottom wall 348a to the vapor chamber 30L. As heat is transferred into the fluid within the vapor chamber 30L, the fluid may boil or vaporize. The boiling or vaporized fluid naturally circulates toward a top of the vapor chamber 30L. In this illustrated embodiment, the top of the vapor chamber 30L includes the cooler feature 340 which includes thermoelectric cooler configured to accelerate the heat transfer. As heat is transferred to the base plate 308 of the heat sink 334, the vaporized or boiled fluid in the vapor chamber 30L condenses back into liquid form and falls back to the bottom of the vapor chamber 30L. The heat transferred to the base plate 308 of the heat sink 334 of the liquid cooling system 30U is then transferred to the cooling liquid 318 that is circulated through the inlet 316 and into the cavity 312 of the liquid cooling system 30U. In some examples, the cooling liquid 314 may be at an appropriate temperature and flow rate to remove a desired amount of heat from the die 102 and the dies 104 of the IC package 20. The heated cooling liquid supply 318 is circulated to the outlet 320 and exits the liquid cooling system 30U as the cooling liquid return 322 (e.g., that is at a higher temperature than the cooling liquid supply 318). The cooling liquid return 322 is circulated back, e.g., to a source of the cooling liquid, to expel the heat (e.g., in a chiller, cooling tower, or other heat exchanger) from the return 322. By forming the heat-dissipating lid module 30 that includes a heat sink 334 configured to facilitate the formation of two cooling systems (e.g., the liquid cooling system and the vapor chamber) and by forming the cooler feature 340 in the vapor chamber, the heat transfer efficiency may be advantageously increased.

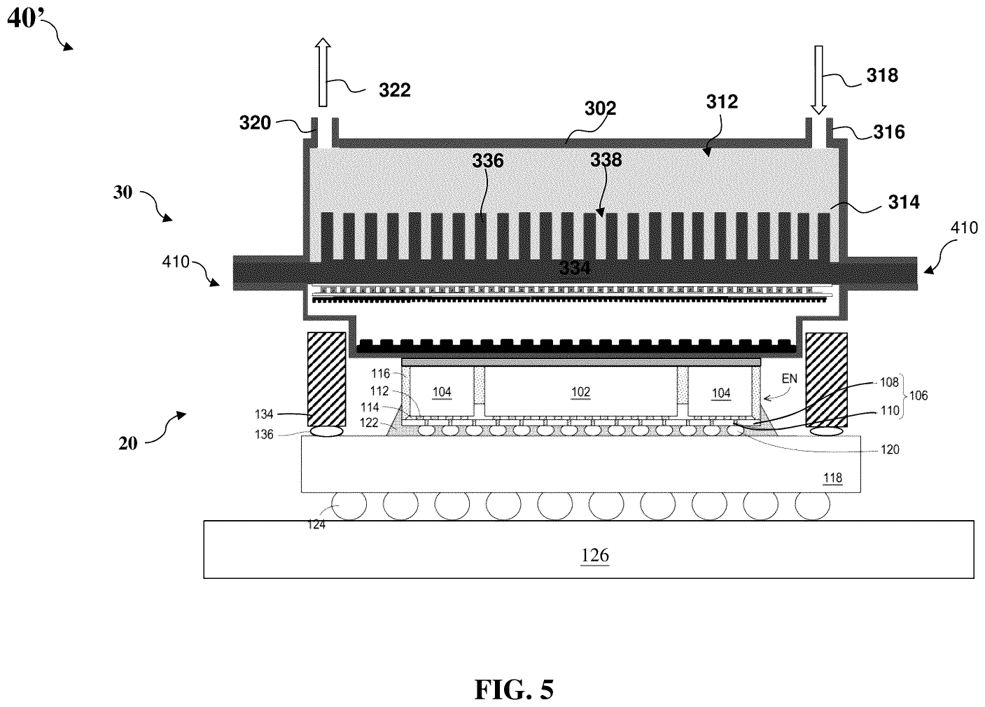

FIG. 5 depicts a cross-sectional view of a first alternative package structure 40′, in portion or entirety, according to various aspects of the present disclosure. The package structure 40′ is similar to the package structure 40 described above with reference to FIGS. 1-4, and one of the differences between the package structure 40′ and the package structure 40 includes that, the heat-dissipating lid module 30 of the package structure 40′ has a different shape. For example, the inlet 316 and outlet 320 may be arranged on the top wall 302, instead of the side walls 310. In another embodiment, each of the top portion 30A, middle portion 30B, and bottom portion 30C of the heat-dissipating lid module 30 of the package structure 40′ includes a branch (e.g., flanges) 410 protruding from its respective main body. Those branches 410 are overlapped and may be then attached together to form the cavity 312 and the chamber 350.

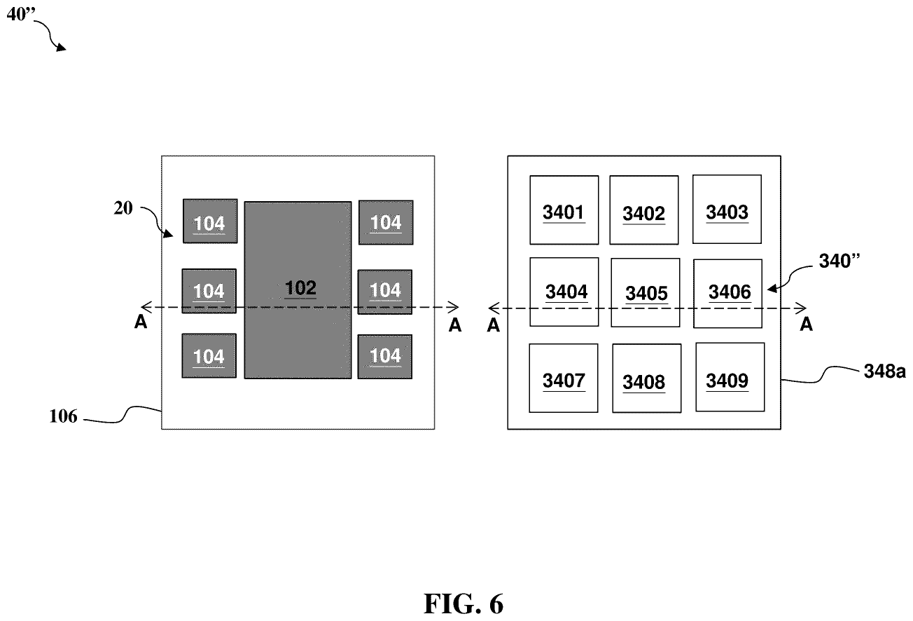

FIG. 6 depicts a schematic plan view illustrating the IC package 20 and a schematic plan view illustrating a cooler feature 340″ of the heat-dissipating lid module 30 of a second alternative package structure 40″, according to some embodiments of the present disclosure. The second alternative package structure 40″ is substantially similar to the package structure 40 or 40′ described above with reference to FIGS. 1-5, one of the differences includes that, the package structure 40″ includes a cooler feature 340″ different than the cooler feature 340. On the left side of FIG. 6, a schematic plan view illustrating the IC package 20 is illustrated, and on the right side of FIG. 6, a schematic plan view illustrating a cooler feature 340″ is illustrated. In this illustrated example, the IC package 20 includes multiple dies (e.g., die 102 and dies 104) over the interposer 106. Different dies may generate different amounts of heat. For example, for embodiments in which the die 102 is a system-on-chip (SoC), and the die 104 is a memory device (e.g., high bandwidth memory HBM devices), the die 102 may generate more heat than the dies 104. To reduce or eliminate hot spots caused by the die 102, the cooler feature 340″ in this depicted example is configured to have multiple discrete thermoelectric coolers (e.g., 3401, 3402, 3403, 3404, 3405, 3406, 3407, 3408, 3409) with different configurations to improve the phase change process at different locations in the vapor chamber 30L. More specifically, for the portion of the cooler feature 340″ that is disposed directly over the die 102, the corresponding thermoelectric coolers (e.g., 3402, 3405, 3408) may include multi-stage thermoelectric coolers (TECs), and for the portion of the cooler feature 340″ that is not disposed directly over the die 102 (e.g., disposed directly over the die 104), the corresponding thermoelectric coolers (e.g., 3401, 3403, 3404, 3406, 3407, 3409) may be single-stage thermoelectric coolers. In an embodiment, each of the thermoelectric coolers 3402, 3405, 3408 may be a two-stage thermoelectric cooler. In another embodiment, the thermoelectric cooler 3405 that is disposed over a central portion of the die 102 may be a three-stage thermoelectric cooler, while each of the thermoelectric cooler 3402 and the thermoelectric cooler 3408 may be a two-stage thermal electric cooler. By providing thermoelectric coolers with different configurations and placing those thermoelectric coolers at different positions, hot spots caused by the die 102 may be eliminated quicker.

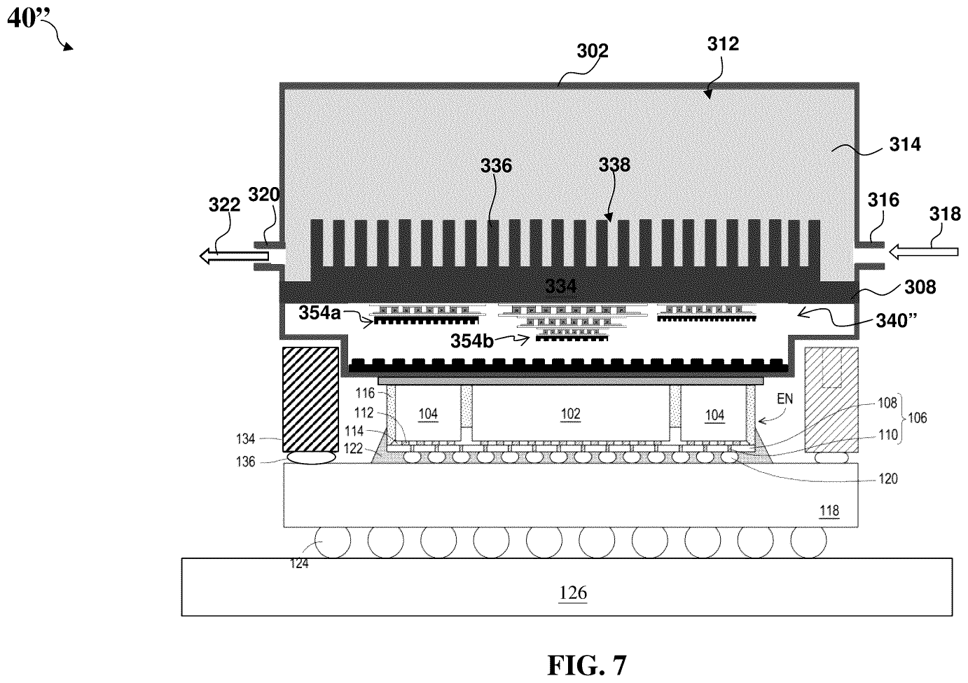

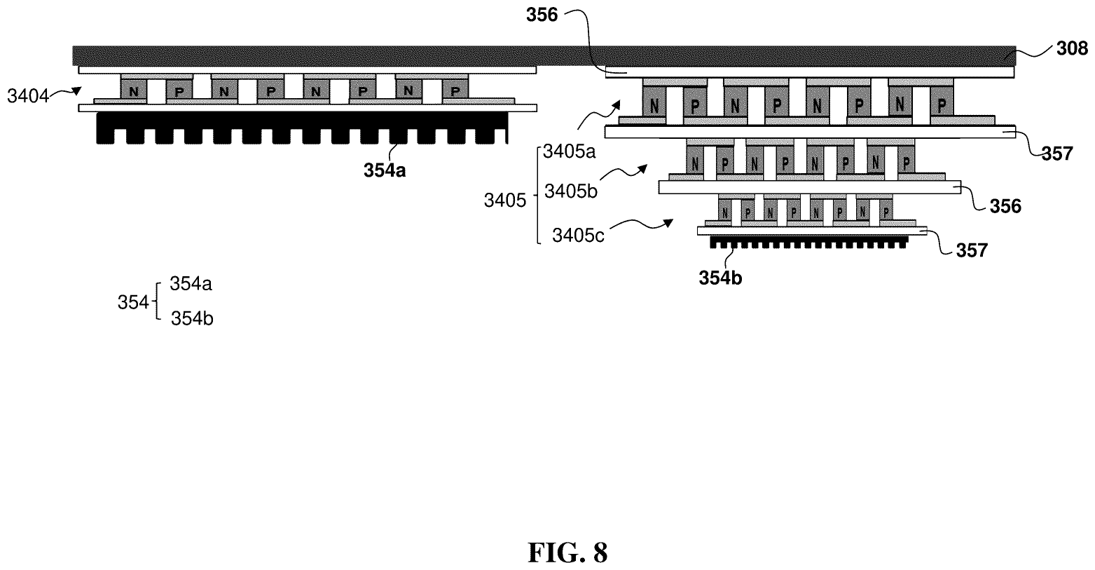

FIG. 7 depicts a fragmentary cross-sectional view of the second alternative package structure 40″ taken along line A-A shown in FIG. 6, according to various aspects of the present disclosure. FIG. 8 depicts an enlarged view of a portion of the package structure 40″ that shows the thermoelectric coolers 3404 and 3405. The cross-sectional view of the second alternative package structure 40″ shown in FIG. 7 is substantially similar to the cross-sectional view represented by FIGS. 4-5, and one of the differences include the arrangement of the cooler feature 340″. Repeated description of the package structure 40″ is omitted for reason of simplicity. In this illustrated embodiment, the thermoelectric cooler 3404 (shown in FIG. 8) is a single-stage thermoelectric cooler that has a structure similar to the portion 340A or 340A′ described with reference to FIGS. 3C and 3D, and repeated description is omitted for reason of simplicity. The thermoelectric cooler 3405 (shown in FIG. 8) is a three-stage thermoelectric cooler and includes a top thermoelectric cooler 3405a, a middle thermoelectric cooler 3405b, and a bottom thermoelectric cooler 3405c. Each of the top thermoelectric cooler, middle thermoelectric cooler, and bottom thermoelectric cooler 3405a-3405c has a structure similar to the portion 340A or 340A′ described with reference to FIGS. 3C and 3D, and repeated description related to the top thermoelectric cooler, middle thermoelectric cooler, and bottom thermoelectric cooler 3405a-3405c is omitted for reason of simplicity. Each of the first thermal conducting plate 356 and the second thermal conducting plate 357 may be a single-layer thermal conducting plate or a dual-layer thermal conducting plate. The wicking structure 354 includes a first wick 354a disposed under the thermoelectric cooler 3404 and a second wick 354b disposed under the thermoelectric cooler 3405. In an embodiment, a distance between the thermoelectric cooler 3404 and the die thereunder (e.g., die 104) is greater than a distance between the thermoelectric cooler 3405 and the die thereunder (e.g., die 102). In various embodiments, to further improve heat dissipation efficiency to reduce or eliminate hot spots caused by the die 102, the second wick 354b disposed under the thermoelectric cooler 3405 may be configured to conduct more heat than the first wick 354a disposed under the thermoelectric cooler 3404. For example, in embodiments where the first wick 354a and the second wick 354b each include a pattered copper structure (e.g., copper grooved wick), the second wick 354b may have more copper fins than the first wick 354a. It is noted that the first wick 354a and the second wick 354b illustrated in FIG. 8 are not drawn to scale.

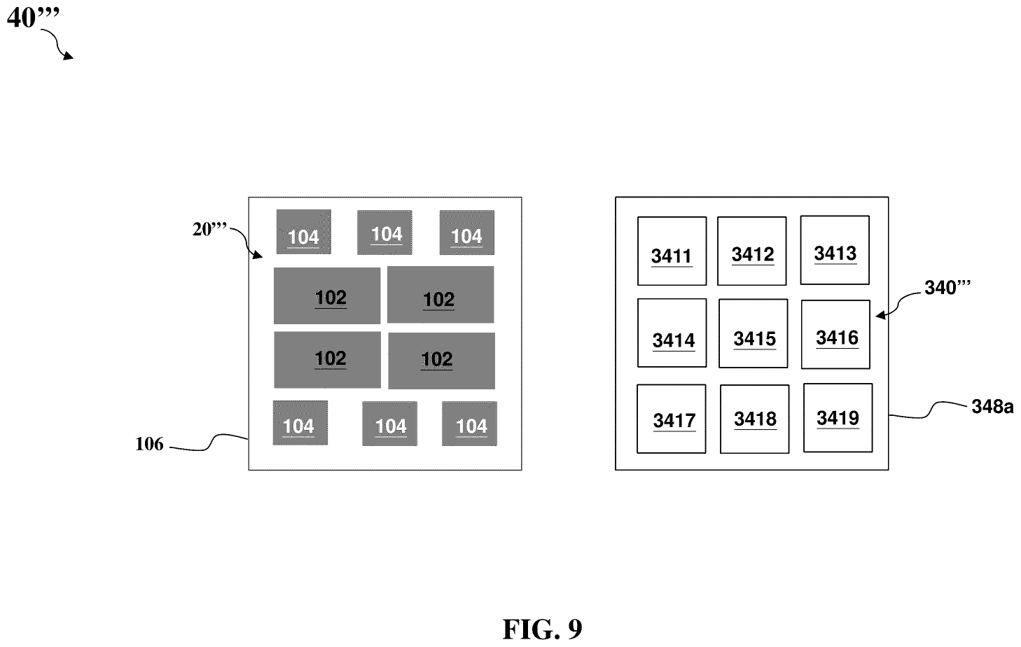

FIG. 9 depicts a schematic plan view illustrating an IC package 20′″ and a schematic plan view illustrating a cooler feature 340′″ of the heat-dissipating lid module 30 of a third alternative package structure 40′″, according to some embodiments of the present disclosure. The third alternative package structure 40′″ is substantially similar to the package structure 40 or 40′ described above with reference to FIGS. 1-5 and the second alternative package structure 40″ described above with reference to FIGS. 6-8, the differences between the package structure 40′″ and the package structure 40/40′/40″ include that, the package structure 40′″ includes an IC package 20′″ different than the IC package 20 and a cooler feature 340′″ different than the cooler feature 340/340′/340″. On the left side of FIG. 9, a schematic plan view illustrating the IC package 20′″ is depicted, and on the right side of FIG. 9, a schematic plan view illustrating a cooler feature 340′− is depicted. In this illustrated example, the IC package 20′″ includes four dies 102 arranged over a central portion of the interposer 106 and six dies 104 on two sides of the four dies 102. Different dies may generate different amounts of heat. For example, for embodiments in which the die 102 is a system-on-chip (SoC), and the die 104 is a memory device (e.g., high bandwidth memory HBM devices), the die 102 may generate more heat than the die 104.

To reduce or eliminate hot spots caused by the dies 102, the cooler feature 340′″ in this depicted example is configured to have multiple discrete thermoelectric coolers (e.g., 3411, 3412, 3413, 3414, 3415, 3416, 3417, 3418, 3419) with different configurations. More specifically, for the portion of the cooler feature 340′″ that is disposed over the dies 104, the corresponding thermoelectric coolers (e.g., 3411, 3412, 3413, 3417, 3418, 3419) may include single-stage thermoelectric coolers (TECs), and for the portion of the cooler feature 340′″ that is disposed directly over the dies 102, the corresponding thermoelectric coolers (e.g., 3414, 3415, 3416) may be multi-stage thermoelectric coolers. In an embodiment, each of the thermoelectric coolers 3414, 3415, 3416 may be a two-stage thermoelectric cooler. In another embodiment, the thermoelectric cooler 3415 that is disposed over the center of the dies 102 may be a three-stage thermoelectric cooler, while each of the thermoelectric cooler 3414 and the thermoelectric cooler 3416 may be a two-stage thermal electric cooler. By providing thermoelectric coolers with different configurations and placing those thermoelectric coolers at different positions, hot spots caused by the dies 102 may be eliminated quicker.

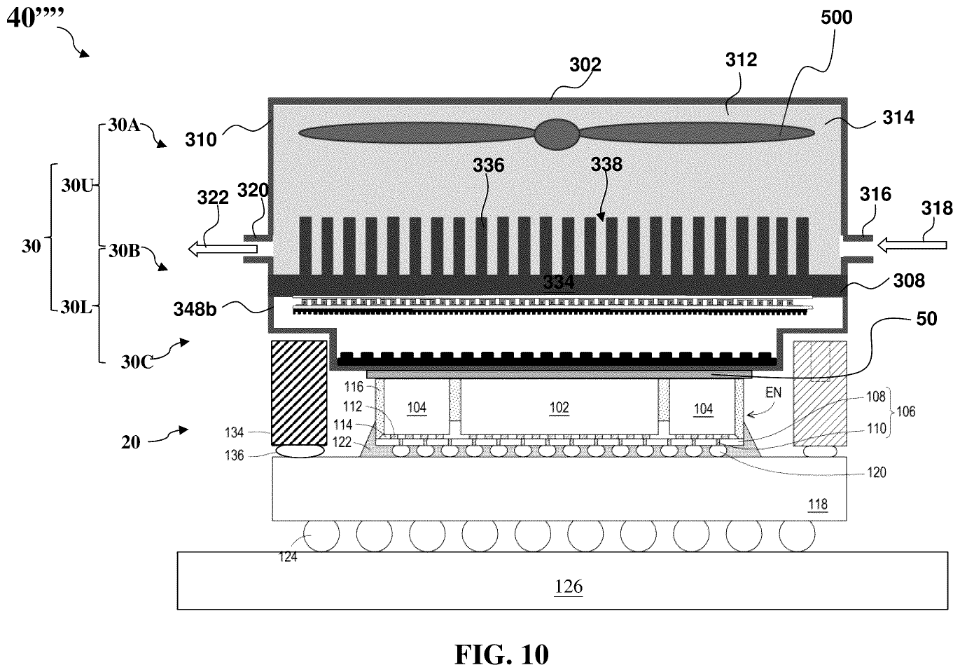

In the above embodiments, the heat-dissipating lid module includes a liquid cooling system 30U thermally coupled to a vapor chamber 30L though a base wall of the liquid cooling system 30U, which is also a top wall of the vapor chamber 30L. FIG. 10 depicts a fragmentary cross-sectional view of a fourth alternative package structure 40″″, according to various aspects of the present disclosure. The package structure 40′″ is substantially similar to the package structure 40, one of the differences between the package structure 40″″ and the package structure 40 includes that the package structure 40″″ also includes an impeller structure 500 installed in the liquid cooling system 30U to pump the cooling liquid 314 to further improve heat dissipation. The impeller structure 500 may be mounted on the inner surface of the top wall 302 or other suitable locations. For embodiments in which chamber 312 is not filled by the cooling liquid 314, instead of using the impeller structure 500, an air-cooling fan or blower structure may be implemented to pump air to improve heat dissipation.

Although not intended to be limiting, one or more embodiments of the present disclosure provide many benefits to a package structure and the formation thereof. For example, the package structure includes a heat-dissipating lid module that can efficiently conduct heat dissipation. In an embodiment, the heat-dissipating lid module includes a first portion configured as a liquid cooling system and a second portion configured as a vapor chamber. The base portion of a heat sink serves as a gas-tight and liquid-tight partition wall to separate the two chambers of the liquid cooling system and the vapor chamber. In some embodiments, thermoelectric coolers are included in the vapor chamber and attached to a bottom surface of the base portion of the heat sink. The thermoelectric coolers may have different configurations to increase phase change process in the vapor chamber to eliminate hot spots associated with dies of the package structure.

The present disclosure provides for many different embodiments. Semiconductor structures and methods of fabrication thereof are disclosed herein. In one exemplary aspect, the present disclosure is directed to a heat-dissipating lid module. The heat-dissipating lid module includes an upper thermally conductive casing, a lower thermally conductive casing, a thermally conductive sidewall, a heat sink thermally coupled to the thermally conductive sidewall, wherein the upper thermally conductive casing, the heat sink, and a portion of the thermally conductive sidewall over the heat sink define a first chamber, the lower thermally conductive casing, the heat sink, and a portion of the thermally conductive sidewall under the heat sink define a second chamber, and a wicking structure disposed in the second chamber.

In some embodiments, the heat sink may include a base portion and a plurality of fins protruding from the base portion, a bottom surface of the base portion faces towards the second chamber, and the plurality of fins protrudes into the first chamber. In some embodiments, the heat-dissipating lid module may also include a thermoelectric cooling device disposed in the second chamber. In some embodiments, the thermoelectric cooling device may include a thermoelectric cooler extending along a bottommost surface of the heat sink. In some embodiments, the wicking structure may include a first portion thermally coupled to the lower thermally conductive casing and a second portion thermally coupled to the thermoelectric cooling device. In some embodiments, the thermoelectric cooling device may include a plurality of discrete thermoelectric coolers attached to a bottommost surface of the heat sink, and each thermoelectric cooler of the plurality of discrete thermoelectric coolers receives a corresponding power supply. In some embodiments, one thermoelectric cooler of the plurality of discrete thermoelectric coolers is a two-stage thermoelectric cooler, and another thermoelectric cooler of the plurality of discrete thermoelectric coolers is a single-stage thermoelectric cooler. In some embodiments, the heat-dissipating lid module may also include a flow of a cooling liquid circulating in the first chamber. In some embodiments, the heat-dissipating lid module may also include an air-cooling fan attached to the upper thermally conductive casing and placed in the first chamber.

In another exemplary aspect, the present disclosure is directed to a package structure. The package structure includes a package substrate, an integrated circuit (IC) package comprising one or more dies and having a first side and a second side opposite the first side, wherein the first side of the IC package is attached to the package substrate, a heat-dissipating lid module attached to the second side of the IC package, wherein the heat-dissipating lid module comprises an upper portion, a lower portion, and a middle portion disposed between and thermally coupled to the upper portion and the lower portion, wherein the middle portion includes a heat sink separating the heat-dissipating lid module into a liquid cooling system and a vapor chamber.

In some embodiments, the heat sink may include a base portion and a plurality of fins protruding from the base portion, wherein a bottom surface of the base portion faces towards the IC package. In some embodiments, the plurality of fins are disposed in a chamber of the liquid cooling system. In some embodiments, the middle portion may also include a thermoelectric cooling device thermally coupled to the heat sink. In some embodiments, the middle portion may include a wicking structure disposed under the heat sink and extending along a bottommost surface of the thermoelectric cooling device. In some embodiments, the thermoelectric cooling device may include a thermoelectric cooler extending along a bottommost surface of the heat sink. In some embodiments, the IC package may include a first die and a second die generating heat greater than the first die, and wherein the thermoelectric cooling device comprises a first thermoelectric cooler over the first die and a second thermoelectric cooler over the second die, and the second thermoelectric cooler is a multi-stage thermoelectric cooler. In some embodiments, the package structure is free of a thermal interface material between the liquid cooling system and the vapor chamber.

In yet another exemplary aspect, the present disclosure is directed to a method. The method includes receiving a heat-dissipating lid module, wherein the heat-dissipating lid module comprises an upper thermally conductive casing, a lower thermally conductive casing, a thermally conductive sidewall, a heat sink thermally coupled to the thermally conductive sidewall, wherein the upper thermally conductive casing, the heat sink, and a portion of the thermally conductive sidewall over the heat sink define a first chamber, wherein the lower thermally conductive casing, the heat sink, and a portion of the thermally conductive sidewall under the heat sink define a second chamber, and a wicking structure disposed in the second chamber, receiving an IC package, wherein the IC package includes a die having a first side and a second side opposite the first side, a package component attached to the first side of the die; and forming a thermal interface material on the second side of the die, and attaching the heat-dissipating lid module to the second side of the die via the thermal interface material.

In some embodiments, the heat-dissipating lid module may also include a thermoelectric cooling device disposed in the second chamber and thermally attached to the heat sink. In some embodiments, the die is a first die, the IC package may include a second die adjacent to the first die and generating more heat than the first die, and the thermoelectric cooling device may also include a first thermoelectric cooler over the first die and a second thermoelectric cooler over the second die, and the second thermoelectric cooler is a multi-stage thermoelectric cooler.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A heat-dissipating lid module comprising:
an upper thermally conductive casing;
a lower thermally conductive casing;
a thermally conductive sidewall;
a heat sink thermally coupled to the thermally conductive sidewall, wherein the upper thermally conductive casing, the heat sink, and a portion of the thermally conductive sidewall over the heat sink define a first chamber, the lower thermally conductive casing, the heat sink, and a portion of the thermally conductive sidewall under the heat sink define a second chamber; and
a wicking structure disposed in the second chamber.

2. The heat-dissipating lid module of claim 1, wherein the heat sink comprises a base portion and a plurality of fins protruding from the base portion, wherein a bottom surface of the base portion faces towards the second chamber, and the plurality of fins protrudes into the first chamber.

3. The heat-dissipating lid module of claim 1, further comprising:
a thermoelectric cooling device disposed in the second chamber.

4. The heat-dissipating lid module of claim 3, wherein the thermoelectric cooling device comprises a thermoelectric cooler extending along a bottommost surface of the heat sink.

5. The heat-dissipating lid module of claim 3, wherein the wicking structure comprises a first portion thermally coupled to the lower thermally conductive casing and a second portion thermally coupled to the thermoelectric cooling device.

6. The heat-dissipating lid module of claim 3, wherein the thermoelectric cooling device comprises a plurality of discrete thermoelectric coolers attached to a bottommost surface of the heat sink, and each thermoelectric cooler of the plurality of discrete thermoelectric coolers receives a corresponding power supply.

7. The heat-dissipating lid module of claim 6, wherein one thermoelectric cooler of the plurality of discrete thermoelectric coolers is a two-stage thermoelectric cooler, and another thermoelectric cooler of the plurality of discrete thermoelectric coolers is a single-stage thermoelectric cooler.

8. The heat-dissipating lid module of claim 1, further comprising: a flow of a cooling liquid circulating in the first chamber.

9. The heat-dissipating lid module of claim 1, further comprising:
an air-cooling fan attached to the upper thermally conductive casing and placed in the first chamber.

10. A package structure comprising:
a package substrate;
an integrated circuit (IC) package comprising one or more dies and having a first side and a second side opposite the first side, wherein the first side of the IC package is attached to the package substrate; and
a heat-dissipating lid module attached to the second side of the IC package, wherein the heat-dissipating lid module comprises:
an upper portion,
a lower portion, and
a middle portion disposed between and thermally coupled to the upper portion and the lower portion, wherein the middle portion includes a heat sink separating the heat-dissipating lid module into a liquid cooling system and a vapor chamber.

11. The package structure of claim 10, wherein the heat sink comprises a base portion and a plurality of fins protruding from the base portion, wherein a bottom surface of the base portion faces towards the IC package.

12. The package structure of claim 11, wherein the plurality of fins are disposed in a chamber of the liquid cooling system.

13. The package structure of claim 11, wherein the middle portion further comprises a thermoelectric cooling device thermally coupled to the heat sink.

14. The package structure of claim 13, wherein the middle portion comprises a wicking structure disposed under the heat sink and extending along a bottommost surface of the thermoelectric cooling device.

15. The package structure of claim 13, wherein the thermoelectric cooling device comprises a thermoelectric cooler extending along a bottommost surface of the heat sink.

16. The package structure of claim 13, wherein the IC package comprises a first die and a second die generating heat greater than the first die, and wherein the thermoelectric cooling device comprises a first thermoelectric cooler over the first die and a second thermoelectric cooler over the second die, and the second thermoelectric cooler is a multi-stage thermoelectric cooler.

17. The package structure of claim 13, wherein the package structure is free of a thermal interface material between the liquid cooling system and the vapor chamber.

18. A method comprising:
receiving a heat-dissipating lid module, wherein the heat-dissipating lid module comprises:
an upper thermally conductive casing,
a lower thermally conductive casing,
a thermally conductive sidewall,
a heat sink thermally coupled to the thermally conductive sidewall, wherein the upper thermally conductive casing, the heat sink, and a portion of the thermally conductive sidewall over the heat sink define a first chamber, wherein the lower thermally conductive casing, the heat sink, and a portion of the thermally conductive sidewall under the heat sink define a second chamber, and
a wicking structure disposed in the second chamber;
receiving an IC package, wherein the IC package includes a die having a first side and a second side opposite the first side, a package component attached to the first side of the die; and
forming a thermal interface material on the second side of the die; and
attaching the heat-dissipating lid module to the second side of the die via the thermal interface material.

19. The method of claim 18, wherein the heat-dissipating lid module further comprises a thermoelectric cooling device disposed in the second chamber and thermally attached to the heat sink.

20. The method of claim 19, wherein the die is a first die, the IC package includes a second die adjacent to the first die and generating more heat than the first die, and wherein the thermoelectric cooling device comprises a first thermoelectric cooler over the first die and a second thermoelectric cooler over the second die, and the second thermoelectric cooler is a multi-stage thermoelectric cooler.
